(19) United States
(12) Patent Application Publication
(10) Pub. No.: US 2026/0223553 A1
(43) Pub. Date: Jul. 30, 2026

(54) DISPLAY PANEL AND DISPLAY DEVICE INCLUDING THE SAME

(71) Applicant: LG Display Co., Ltd., Seoul (KR)

(72) Inventors: Kyu-Hwang Lee, Paju-si (KR); Jungho Bang, Paju-si (KR); Dongkyu Lee, Goyang-si (KR); Munchan Kang, Goyang-si (KR)

(73) Assignee: LG Display Co., Ltd., Seoul (KR)

(21) Appl. No.: 19/395,832

(22) Filed: Nov. 20, 2025

(30) Foreign Application Priority Data
Jan. 24, 2025 (KR) 10-2025-0011491

(51) Int. Cl. H10K 59/124; H10K 59/131; H10K 102/00

(52) U.S. Cl. CPC H10K 59/124; H10K 59/131; H10K 2102/311

(57) ABSTRACT

A display panel has a front area including a display area and a non-display area outside the display area, a rear area under the front area, and a bendable area connected between the front area and the rear area. The display panel is bent in the bending area and includes: an organic insulating film disposed in the front area, the rear area, and the bendable area and having a curvature in the bendable area; and a signal line on the organic insulating film in the bendable area. The organic insulating film may include a plurality of regions having different thicknesses in the bendable area.

### CROSS REFERENCE TO RELATED APPLICATION

The present application claims priority to Korean Patent Application No. 10-2025-0011491, filed on Jan. 24, 2025, the entire contents of which are incorporated herein by reference for all purposes.

### BACKGROUND

### Field

The present disclosure relates to a display panel and a display device including the same.

### Description of Related Art

A display device is applied to various electronic devices, such as a TV, a smartphone, a laptop computer, and a tablet. To this end, research is being conducted to develop a thin, light weight, and low power consuming display device

Examples of the display device include an LCD (Liquid Crystal Display) device, an FED (Field Emission Display) device, and an OLED (Organic Light-emitting Display) device.

A bezel area of the display device may include an area surrounding an outer side of a display area of the display panel. The bezel area may protect edges of the display panel and internal electronic components from external impact, pressure, or external damage. The bezel area may be visually recognized by a user and thus may be a factor that degrades a sense of immersion in an image emitted from the display area.

Accordingly, recently, there is an increasing demand for a display device implementing a narrow bezel with a reduced bezel area not displaying a screen of the display device or a zero bezel that substantially has an effect of not having a bezel area.

### SUMMARY

As a flexible substrate is applied to a display panel, the display panel may include a bendable area in which a portion of the display panel is bent such that a pad area is hidden under a display area. The bendable area may be disposed in a lower side in a plan view of the display panel.

The bendable area may include a plurality of signal lines to transmit various signals to pixels of the display area.

As the bendable area is bent to be disposed under the display panel to implement the narrow bezel or the zero bezel, stress may be applied to the bendable area. When the stress is applied to the bendable area, cracks may occur in signal lines disposed in the bendable area such that the signal lines may be damaged. When the signal lines are damaged, it is difficult to transmit various signals or power to the display area, and thus the defect rate of the display device may increase.

Accordingly, through various experiments, the inventors of the present disclosure have invented a display device capable of preventing or suppressing occurrence of a weak point where stress is concentrated when a bendable area is bent.

A purpose to be achieved according to one or more embodiments of the present disclosure is to provide a display device capable of preventing or protecting signal lines from being damaged by stress applied to a bendable area.

Another purpose to be achieved according to one or more embodiments of the present disclosure is to provide a display device capable of reducing a bezel area while strengthening the rigidity of the bendable area.

Purposes according to various embodiments of the present disclosure are not limited to the above-mentioned purposes. Other purposes and advantages according to the present disclosure not specifically mentioned may be understood by those skilled in the art based on following descriptions, and may be more clearly understood based on example embodiments according to the present disclosure. Further, the purposes and advantages according to various embodiments of the present disclosure may be understood or realized using means shown in the claims or combinations thereof.

To achieve these objects and other advantages and in accordance with purposes of the present disclosure, as embodied and broadly described herein, a display panel according to one or more example embodiments of the present disclosure has a front area including a display area and a non-display area outside the display area, a rear area under the front area, and a bendable area connected between the front area and the rear area, the display panel being bent in the bending area and including: an organic insulating film disposed in the front area, the rear area, and the bendable area and having a curvature in the bendable area; and a signal line on the organic insulating film in the bendable area, wherein the organic insulating film includes a plurality of regions having different thicknesses in the bendable area.

According to one or more embodiments of the present disclosure, the organic insulating film disposed under the signal line and in the bendable area includes the plurality of areas spaced apart from each other and arranged in the bendable area, wherein the plurality of areas of the organic insulating film have different thicknesses. In this regard, the organic insulating film may be a planarization layer or a substrate. This may prevent or reduce an area onto which the stress is concentrated due to the asymmetrical curvature of the substrate in the bending operation from occurring in the bendable area.

The rigidity of the bendable area of the non-display area NDA of the substrate SUB may be reinforced, thereby preventing or suppressing defects such as cracks from occurring in the signal line extending from the display area across the bendable area to the pad area.

According to one or more embodiments of the present disclosure, the organic insulating film disposed under the signal line and in the bendable area includes the plurality of areas spaced apart from each other and arranged in the bent area, wherein the plurality of areas of the organic insulating film have different thicknesses. In this regard, the organic insulating film may be a planarization layer or a substrate. Thus, the curvature of the signal line may be adapted to prevent or suppress a stress weakness point from occurring.

This may prevent or protect the signal line from being damaged under the stress in the operation of bending the bendable area. This may reinforce the rigidity of the bendable area while further reducing the bezel area visually recognized from the outside.

According to example embodiments of the present disclosure, the defect rate of the display device due to the damage of the signal line can be lowered, so that the production energy required for additional production of the display device may be reduced, thereby reducing the emission of greenhouse gas.

Effects of the present disclosure are not limited to the effects mentioned above, and other effects not mentioned may be clearly understood by those skilled in the art from the description as set forth below.

In addition to the above effects, specific effects of the present disclosure are described together in, or may be understood from, the description of specific details for implementing the example embodiments of the present disclosure provided below.

### BRIEF DESCRIPTION OF THE DRAWINGS

The accompanying drawings, which are included to provide a further understanding of the present disclosure and are incorporated in and constitute a part of this application, illustrate example embodiments of the present disclosure and together with the description serve to explain the principles of the disclosure.

FIGS. 1 and 2 are diagrams illustrating a display device according to example embodiments of the present disclosure.

FIG. 3 is a cross-sectional view taken along a line I-I′ in FIG. 1.

FIG. 4 is a diagram illustrating an example cross-sectional view along a line II-II′ in FIG. 2.

FIG. 5 is a diagram illustrating an area III of FIG. 4.

FIGS. 6 and 7 are diagrams illustrating a display device according to another example embodiment of the present disclosure.

FIG. 8 is a diagram illustrating a bendable area according to another example embodiment of the present disclosure.

FIG. 9 is a diagram illustrating a bendable area according to still another example embodiment of the present disclosure.

FIGS. 10 and 11 are diagrams illustrating stress during a bending operation.

FIG. 12 is a diagram illustrating a bendable area according to still yet another example embodiment of the present disclosure.

### DETAILED DESCRIPTION

Advantages and features of the present disclosure, and a method of achieving the advantages and features will become apparent with reference to example embodiments described below in detail together with the accompanying drawings. However, the present disclosure is not limited to the example embodiments as disclosed below but may be implemented in various other forms. Thus, these embodiments are set forth only to make the present disclosure more complete, and to inform the scope of the present disclosure more fully to those of ordinary skill in the technical field to which the present disclosure belongs. The protected scope of the present disclosure may be defined by the scope of the claims and their equivalents.

For simplicity and clarity of illustration, elements in the drawings are not necessarily drawn to scale. The same reference numbers in different drawings represent the same or similar elements, and as such perform similar functionality, unless otherwise specified. Further, descriptions and details of well-known steps and elements may be omitted for simplicity of the description. Furthermore, in the following detailed description of example embodiments of the present disclosure, numerous specific details may be set forth to provide a thorough understanding of the present disclosure. However, it should be understood that the present disclosure may be practiced without these specific details. In other instances, well-known methods, procedures, components, and circuits may be not described in detail so as not to unnecessarily obscure aspects of the present disclosure. Examples of various embodiments are illustrated and described further below. It should be understood that the description herein is not intended to limit the claims to the specific embodiments described. On the contrary, it is intended to cover alternatives, modifications, and equivalents as may be included within the spirit and scope of the present disclosure as defined by the appended claims and their equivalents.

A shape, a size, a ratio, an angle, a number, etc. disclosed in the drawings for illustrating example embodiments of the present disclosure are illustrative, and the present disclosure is not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It should be further understood that terms like “comprise,” “comprising,” “include,” and “including,” where used in this disclosure, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression like “at least one of,” where preceding a list of elements, may modify the entire list of elements and not the individual elements of the list. In interpretation of numerical values, an error or tolerance therein may occur even where there is no explicit description thereof.

In addition, it should also be understood that when a first element or layer is referred to as being present “on” a second element or layer, the first element may be disposed directly on the second element or may be disposed indirectly on the second element with a third element or layer being disposed between the first and second elements or layers. It should be understood that, where an element or layer is referred to as being “connected to” or “coupled to” another element or layer, it may be directly connected to or coupled to the other element or layer, or one or more intervening elements or layers may be present therebetween. In addition, it should also be understood that, where an element or layer is referred to as being “between” two elements or layers, it may be the only element or layer between the two elements or layers, or one or more intervening elements or layers may also be present.

Further, as used herein, where a layer, film, area, plate, or the like is described as being disposed “on” or “on top” of another layer, film, area, plate, or the like, the former may directly contact the latter, or still another layer, film, area, plate, or the like may be disposed between the former and the latter. As used herein, where a layer, film, area, plate, or the like is described as being “directly” disposed “on” or “on top” of another layer, film, area, plate, or the like, the former directly contacts the latter, and still another layer, film, area, plate, or the like is not disposed between the former and the latter. Further, as used herein, where a layer, film, area, plate, or the like is described as being disposed “beneath” or “under” another layer, film, area, plate, or the like, the former may directly contact the latter, or still another layer, film, area, plate, or the like may be disposed between the former and the latter. As used herein, where a layer, film, area, plate, or the like is described as being “directly” disposed “beneath” or “under” another layer, film, area, plate, or the like, the former directly contacts the latter, and still another layer, film, area, plate, or the like is not disposed between the former and the latter.

In descriptions of temporal relationships, for example, temporal precedent relationships between two events, such as “after,” “subsequent to,” “before,” etc., another event may occur therebetween unless a more specific phrase like “directly after,” “directly subsequent,” or “directly before” is indicated.

Where a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It should be understood that, although terms like “first,” “second,” “third,” and so on may be used herein to describe various elements, components, areas, layers and/or periods, these elements, components, areas, layers and/or periods should not be limited by these terms. These terms are used to refer to one element, component, area, layer or period separately from another element, component, area, layer or period. Thus, a first element, component, area, layer or period as described herein could be termed a second element, component, area, layer or period, and vice versa, without departing from the spirit and scope of the present disclosure.

The features of the various embodiments of the present disclosure may be partially or entirely combined with each other, and may be technically associated with each other or operate with each other. The embodiments may be implemented independently of each other or may be implemented together in an association relationship.

In interpreting a numerical value, the value is to be interpreted as including an error range unless otherwise specified.

Unless otherwise defined, all terms including technical and scientific terms used herein have the same meaning as commonly understood by one of ordinary skill in the art to which this disclosure belongs. It should be further understood that terms, such as those defined in commonly used dictionaries, should be interpreted as having a meaning that is consistent with their meaning in the context of the relevant art and should not be interpreted in an idealized or overly formal sense unless expressly so defined herein.

As used herein, “embodiments,” “examples,” “aspects,” and the like should not be construed such that any embodiment, example, aspect, or design as described is superior to or advantageous over other embodiments, examples, aspects, or designs.

Further, unless otherwise stated or clear from the context, the term “or” means “inclusive or” rather than “exclusive or.” That is, unless otherwise stated or clear from the context, the expression that “x uses a or b” means one of natural inclusive permutations.

The terms used in the description below have been selected as being general and universal in the related technical field. However, there may be other terms that are equivalent, similar, or appropriate depending on the development and/or change of technology, convention, preference of technicians, etc. Therefore, the terms used in the description below should not be understood as limiting technical ideas but should be understood as examples of the terms for illustrating embodiments.

Further, in a specific case, a term may be arbitrarily selected by the applicant, and in this case, the detailed meaning thereof will be described in a corresponding description period. Therefore, the terms used in the description below should be understood based on not simply the name of the terms, but the meaning of the terms and the contents throughout the Detailed Description.

In description of flow of a signal, for example, where a signal is described as being delivered from a node A to a node B, this may include a case where the signal is transferred from the node A to the node B via another node unless a more specific phrase like “immediately transferred” or “directly transferred” is used.

Throughout the present disclosure, if used, “A and/or B” means A, B, or A and B, unless otherwise specified, and “C to D” means C inclusive to D inclusive unless otherwise specified.

“At least one” should be understood to include any combination of one or more of listed components. For example, at least one of first, second, and third components encompasses not only a first, second, or third component individually, but also all combinations of two or more of the first, second, and third components.

Hereinafter, example embodiments of the present disclosure will be described with reference to the attached drawings. A scale of each of components as shown in the drawings may be different from an actual scale thereof for convenience of illustration. Therefore, the present disclosure is not limited to the scale as shown in the drawings.

As used herein, a first direction, a second direction, and a third direction, or an X-axis direction, a Y-axis direction, and a Z-axis direction should not be interpreted only as having a geometric relationship with each other in which the first direction, the second direction, and the third direction are perpendicular to each other or the X-axis direction, the Y-axis direction, and the Z-axis direction are perpendicular to each other, but may be interpreted as having a geometric relationship with each other in which the first direction, the second direction, and the third direction interest each other at an angle other than 90 degrees (°) or the X-axis direction, the Y-axis direction, and the Z-axis direction are interest each other at an angle other than 90 degrees (°) within a range in which a configuration of the present disclosure may work functionally.

Hereinafter, a display device according to example embodiments of the present disclosure will be described with reference to the drawings.

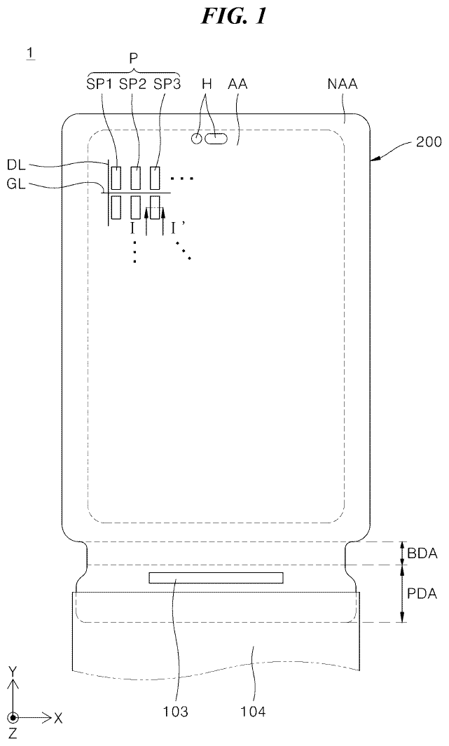

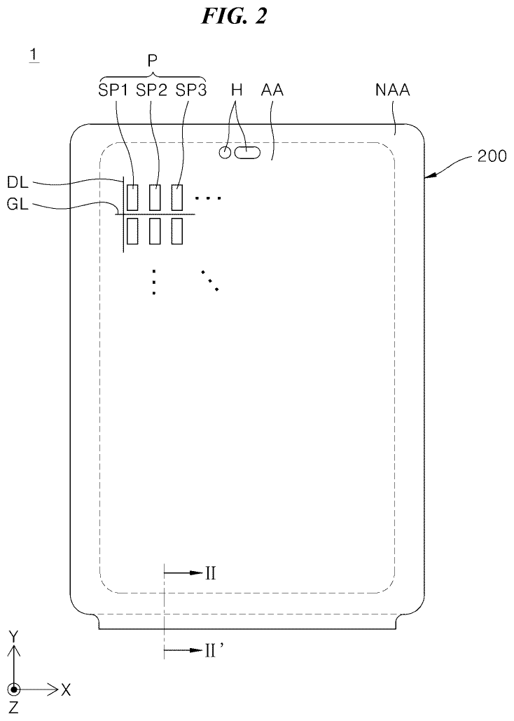

FIGS. 1 and 2 are diagrams illustrating a display device according to example embodiments of the present disclosure. FIG. 1 illustrates a state in which the example display device is not bent, and FIG. 2 illustrates a state in which the example display device is bent.

As shown in FIGS. 1 and 2, a display device 1 according to an example embodiment of the present disclosure may include a display panel 200 including a display area AA and a non-display area NAA, a driving circuit chip 103, a printed circuit board 104, etc.

The display area AA is an area in which an image is displayed, and a plurality of pixels P, data lines DL, and gate lines GL may be disposed in the display area AA. The non-display area NAA may be an area in which no image is displayed. The non-display area NAA may be located in the peripheral area (or an edge area) of the display panel 200. However, embodiments of the present disclosure are not limited thereto. For example, an area other than a light emission area in which light is emitted to the outside in the display area AA may be referred to as the non-display area NAA. A bezel area of the display device may be defined by the non-display area NAA. The bezel area or the non-display area NAA may surround the outside of the display area AA. A bendable area BDA and a pad area PDA may be disposed in a lower end of the non-display area NAA.

Lines for providing an electrical signal to the display area AA or receiving an electrical signal from the display area AA may be disposed in the non-display area NAA. For example, a gate driver for supplying a gate signal to the plurality of sub-pixels SP1, SP2, and SP3 of the display area AA may be disposed in the non-display area NAA. The gate driver may be disposed at each of right and left edges of the non-display area NAA in a gate in panel (GIP) manner, but embodiments of the present disclosure is not limited thereto. The gate driver may transmit a gate signal via the gate lines GL.

The non-display area NAA may include a driving circuit chip 103 in a pad area PDA in which a plurality of pads are disposed. The driving circuit chip 103 may transmit a data signal to the plurality of sub-pixels SP1, SP2, and SP3 via the plurality of data lines DL in the display area AA. For example, the driving circuit chip 103 may be a data driving circuit chip. However, embodiments of the present disclosure are not limited thereto.

The gate lines GL may extend in a first direction X of the display panel 200, and the data lines DL may intersect the gate lines GL and extend in a second direction Y of the display panel 200 in a plan view of the display device.

The data lines DL in the display area AA may extend toward the bendable area BDA and may be electrically connected to the driving circuit chip 103. In an example, the signal lines electrically connecting the data lines DL and the driving circuit chip 103 to each other may extend from a portion of the non-display area NAA between the bendable area BDA and the display area AA to the bendable area BDA and to the pad area PDA so as to be electrically connected to the printed circuit board 104. The signal lines extending to the bendable area BDA may be bent along a shape of the bendable area BDA when the bendable area BDA is bent. This will be described later.

The bendable area BDA of the display panel 200 may be bent such that the printed circuit board 104 is disposed under the display area AA of the display panel 200. The printed circuit board 104 may include a control circuit chip for controlling the gate driver. Accordingly, the non-display area NAA recognizable by a viewer in front of the display device 1 may be reduced, and a narrow bezel may be implemented.

The display area AA may include a plurality of pixels P and one or more holes H. The hole(s) H may be an area in which an electronic component for adding various functions to the display device 1 is disposed. For example, the electronic component may include a camera module for taking a picture or an image, or may include various sensor devices for detecting an external object. The sensor device may include at least one of a proximity sensor, a gesture sensor, a color sensor, a biometric sensor, and an infrared sensor. However, embodiments of the present disclosure are not limited thereto.

One pixel P may include a plurality of sub-pixels SP1, SP2, and SP3. An image may be displayed in the display area AA through the plurality of sub-pixels SP1, SP2, and SP3. The plurality of sub-pixels SP1, SP2, and SP3 may be arranged in an array in the display area AA. In an example, the plurality of sub-pixels SP1, SP2, and SP3 may be arranged in a matrix manner and may be spaced apart from each other in the first direction of the display area AA and the second direction intersecting the first direction. The first direction may be a horizontal direction, an X-axis direction, or a row direction, and the second direction may be a vertical direction, a Y-axis direction, or a column direction. However, the present disclosure is not limited thereto, and the arrangement shape, arrangement order, and arrangement direction of the sub-pixels SP1, SP2, and SP3 may be variously changed.

The sub-pixels SP1, SP2, and SP3 may be implemented to emit light of the same color, such as white light. Alternatively, the sub-pixels SP1, SP2, and SP3 may be implemented to emit light of different colors, such as red, green, and blue colors.

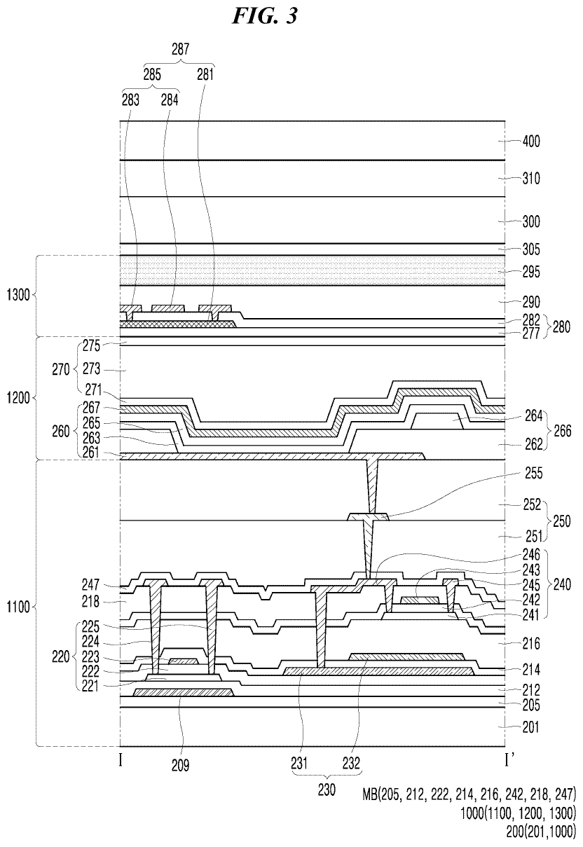

FIG. 3 is a cross-sectional view taken along a line I-I′ in FIG. 1. FIG. 3 schematically illustrates one example sub-pixel of a display device. In the present disclosure, for convenience of description, an example of a configuration of one sub-pixel is described. However, the present disclosure is not limited thereto.

As illustrated in FIG. 3, the display panel 200 may include a driving array 1000 disposed on the substrate 201. A polarizing layer 300, an optical adhesive member 310, and a cover substrate 400 may be disposed on the driving array 1000.

The driving array 1000 may include a pixel driving circuit 1100, a light-emitting area 1200, and a touch area 1300. The pixel driving circuit 1100 may include a plurality of transistors 220 and 240 and a storage capacitor 230. The light-emitting area 1200 may include a light-emitting element 260, and the touch area 1300 may include a touch sensor 287.

One sub-pixel may include the light-emitting area 1200 including the light-emitting element 260 and the pixel driving circuit 1100 that applies a driving current to the light-emitting element 260 of the light-emitting area 1200. The pixel driving circuit 1100 is disposed on the substrate 201, and the light-emitting area 1200 is disposed on the pixel driving circuit 1100. The touch area 1300 may be disposed on the light-emitting area 1200. However, embodiments of the present disclosure are not limited thereto. The plurality of transistors 220 and 240 of the pixel driving circuit 1100 may include a first transistor 220 and a second transistor 240.

The substrate 201 may be a flexible plastic substrate. Where the substrate 201 is formed as a plastic film, the substrate 201 may include multiple layers made of an insulating material. A first buffer layer 205 may be disposed on the substrate 201. The first buffer layer 205 may cover a surface of the substrate 201. The first buffer layer 205 may reduce or prevent penetration of moisture, oxygen, or impurities through the substrate 201. The first buffer layer 205 may be embodied as a single layer or a multilayer made of an inorganic insulating material, such as silicon oxide (SiOx) or silicon nitride (SiNx). The first buffer layer 205 may entirely cover the surface of the substrate 201 in the display area AA. For example, the first buffer layer 205 may extend to the non-display area NAA surrounding the periphery of the display area AA.

A light-shielding layer 209 may be disposed on the first buffer layer 205. The light-shielding layer 209 may prevent or block external light from being incident on the transistor. To this end, the light-shielding layer 209 may include an opaque metal material. A second buffer layer 212 may be disposed on the light-shielding layer 209. The second buffer layer 212 may protect the transistor from moisture, oxygen, or impurities. The second buffer layer 212 may be embodied as a single layer or a multilayer made of an inorganic insulating material, such as silicon oxide (SiOx) or silicon nitride (SiNx). However, embodiments of the present disclosure are not limited thereto. The second buffer layer 212 may entirely cover the surface of the substrate 201 in the display area AA. For example, the second buffer layer 212 may extend to the non-display area NAA surrounding the periphery of the display area AA.

The first transistor 220 may be disposed on the second buffer layer 212. The first transistor 220 may include a first semiconductor layer 221, a first gate insulating layer 222, a first gate electrode 223, a first source electrode 224, and a first drain electrode 225. In an example, the first transistor 220 may be a switching transistor.

The first semiconductor layer 221 may include a channel area and source/drain areas. An area of the first semiconductor layer 221 overlapping the first gate electrode 223 in the vertical direction may be a channel area. The source/drain areas may be disposed respectively at opposing sides of the channel area. The first semiconductor layer 221 may include one of a polysilicon semiconductor layer and a low-temperature polysilicon semiconductor layer, or a combination thereof. In another example, the first semiconductor layer 221 may include an oxide semiconductor layer. For example, the first semiconductor layer 221 may include at least one of an oxide semiconductor material, such as IGZO (Indium Gallium Zinc Oxide) or IZO (Indium Zinc Oxide).

Where the first semiconductor layer 221 includes the oxide semiconductor layer, the first transistor 220 may be embodied as an oxide thin-film transistor. The first semiconductor layer 221 may be disposed to overlap the light-shielding layer 209 in the vertical direction. The light-shielding layer 209 may prevent or block external light from being incident on the first semiconductor layer 221.

The first gate insulating layer 222 may be disposed between the first semiconductor layer 221 and the first gate electrode 223. The first gate insulating layer 222 may extend outwardly while covering the first semiconductor layer 221. The first gate insulating layer 222 may be embodied as a single layer or a stack of a plurality of layers made of an inorganic insulating material, such as silicon oxide (SiOx) or silicon nitride (SiNx). The first gate insulating layer 222 may entirely cover the surface of the substrate 201 in the display area AA. For example, the first gate insulating layer 222 may extend to the non-display area NAA surrounding the periphery of the display area AA.

The first gate electrode 223 may be disposed on the first gate insulating layer 222. A first interlayer insulating layer 214 may be disposed on the first gate electrode 223. The first interlayer insulating layer 214 may be embodied as a single layer or a stack of multiple layers made of an inorganic insulating material, such as silicon oxide (SiOx) or silicon nitride (SiNx). In an example, the first interlayer insulating layer 214 may extend to the non-display area NAA surrounding the periphery of the display area AA.

The first source electrode 224 and the first drain electrode 225 may be electrically connected to the first semiconductor layer 221.

The storage capacitor 230 may include a first storage electrode 231 and a second storage electrode 232. For example, the first storage electrode 231 and the first gate electrode 223 may be formed on the same layer (e.g., the first gate insulating layer 222). For example, the first storage electrode 231 may be disposed on the first gate insulating layer 222 and at a position horizontally spaced apart from the first gate electrode 223. The first storage electrode 231 may be made of the same material as that of the first gate electrode 223. The second storage electrode 232 may be disposed on the first interlayer insulating layer 214 so as to overlap the first storage electrode 231 in the vertical direction.

Each of the first storage electrode 231 and the second storage electrode 232 may be embodied as a single layer or as a stack of multiple layers made of one of molybdenum (Mo), aluminum (Al), chromium (Cr), gold (Au), titanium (Ti), nickel (Ni), neodymium (Nd), and copper (Cu) or an alloy thereof. However, embodiments of the present disclosure are not limited thereto.

A second interlayer insulating layer 216 may be disposed on the second storage electrode 232. The second interlayer insulating layer 216 may be embodied as a single layer or a stack of multiple layers made of an inorganic insulating material, such as silicon oxide (SiOx) or silicon nitride (SiNx). In an example, the second interlayer insulating layer 216 may extend to the non-display area NAA surrounding the periphery of the display area AA.

The second transistor 240 may be disposed on the second interlayer insulating layer 216 so as to be spaced apart from the first transistor 220. The second transistor 240 may be electrically connected to the first transistor 220. For example, the second transistor 240 may include a second semiconductor layer 241, a second gate insulating layer 242, a second gate electrode 243, a second source electrode 245, and a second drain electrode 246. In an example, the second transistor 240 may be a driving transistor electrically connected to the light-emitting element 260.

The second semiconductor layer 241 may include a channel area and source/drain areas. An area of the second semiconductor layer 241 overlapping the second gate electrode 243 in the vertical direction may be a channel area. The source/drain areas may be disposed respectively at opposing sides of the channel area. The second semiconductor layer 241 may include an oxide semiconductor layer. For example, the second semiconductor layer 241 may include an oxide semiconductor material, such as indium gallium zinc oxide (IGZO) or indium zinc oxide (IZO). In an example, the second semiconductor layer 241 may be disposed to overlap the storage capacitor 230 in the vertical direction. Accordingly, the storage capacitor 230 may prevent or block the external light entering through the substrate 201 from being incident on the second semiconductor layer 241. Accordingly, this may prevent or protect the characteristics of the second transistor 240 from being changed by the external light.

The second gate insulating layer 242 may be disposed between the second semiconductor layer 241 and the second gate electrode 243. The second gate insulating layer 242 may extend outwardly while covering the second semiconductor layer 241. For example, the second gate insulating layer 242 may extend to the non-display area NAA surrounding the periphery of the display area AA. The second gate insulating layer 242 may be embodied as a single layer or a stack of a plurality of layers made of an inorganic insulating material, such as silicon oxide (SiOx) or silicon nitride (SiNx).

Each of the first gate electrode 223 or the second gate electrode 243 may be embodied as a single layer or a stack of multiple layers made of one of molybdenum (Mo), aluminum (Al), chromium (Cr), gold (Au), titanium (Ti), nickel (Ni), neodymium (Nd), and copper (Cu), or an alloy thereof. However, an example of the material is not limited thereto.

A third interlayer insulating layer 218 may be disposed on the second gate electrode 243. The third interlayer insulating layer 218 may include an insulating material. For example, the third interlayer insulating layer 218 may include an inorganic insulating material, such as silicon oxide (Six), silicon nitride (SiNx), or silicon oxynitride (SiON), and may be embodied as a single layer or a stack of multiple layers. In an example, the third interlayer insulating layer 218 may extend to the non-display area NAA surrounding the periphery of the display area AA.

The first source electrode 224, the first drain electrode 225, the second source electrode 245, and the second drain electrode 246 may be disposed on the third interlayer insulating layer 218.

The first source electrode 224 and the first drain electrode 225 may extend through the third interlayer insulating layer 218, the second gate insulating layer 242, the second interlayer insulating layer 216, the first interlayer insulating layer 214, and the first gate insulating layer 222 so as to be in direct contact with and be electrically connected to the source/drain areas of the first semiconductor layer 221, respectively.

The second source electrode 245 and the second drain electrode 246 may extend through the third interlayer insulating layer 218 and the second gate insulating layer 242 so as to directly contact and be electrically connected to the source/drain areas of the second semiconductor layer 241, respectively. The second drain electrode 246 of the second transistor 240 may be electrically connected to the storage capacitor 230. For example, a portion of the second drain electrode 246 may extend through the third interlayer insulating layer 218, the second gate insulating layer 242, the second interlayer insulating layer 216, and the first interlayer insulating layer 214 so as to be in direct contact with and be electrically connected to the first storage electrode 231 of the storage capacitor 230.

Each of the first source electrode 224, the first drain electrode 225, the second source electrode 245, and the second drain electrode 246 may be embodied as a single layer or a stack of multiple layers made of one of molybdenum (Mo), aluminum (Al), chromium (Cr), gold (Au), titanium (Ti), nickel (Ni), neodymium (Nd), and copper (Cu), or an alloy thereof. However, embodiments of the present disclosure are not limited thereto.

In an example, each of the first source electrode 224 and the first drain electrode 225 may have a stack structure of titanium layer/aluminum layer/titanium layer (Ti/Al/Ti).

A passivation layer 247 may be disposed on the first source electrode 224, the first drain electrode 225, the second source electrode 245, and/or the second drain electrode 246. The passivation layer 247 may include an inorganic insulating material, such as silicon oxide, silicon nitride, and silicon oxynitride, and may be embodied as a single layer or a stack of multiple layers. The passivation layer 247 may protect the pixel driving circuit disposed thereunder. The passivation layer 247 may extend to the non-display area NAA surrounding the periphery of the display area AA.

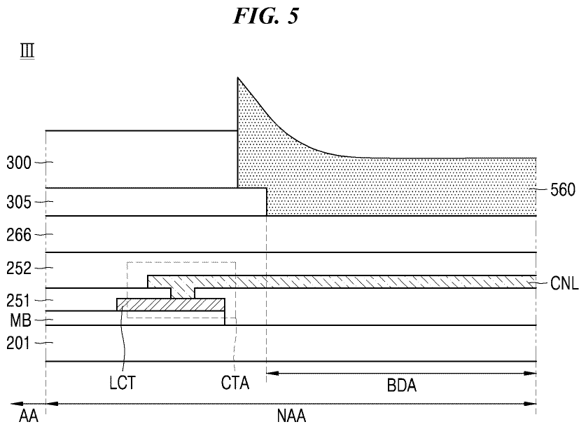

The inorganic insulating layers 205, 212, 222, 214, 216, 242, 218, and 247 disposed on the substrate 201 may be vertically stacked in the non-display area NAA to form an inorganic insulating structure MB (see also, e.g., FIG. 5). For example, the inorganic insulating structure MB may include the first buffer layer 205, the second buffer layer 212, the first gate insulating layer 222, the first interlayer insulating layer 214, the second interlayer insulating layer 216, the second gate insulating layer 242, the third interlayer insulating layer 218, and the passivation layer 247. However, embodiments of the present disclosure are not limited thereto.

A planarization layer 250 may be disposed on the passivation layer 247. The planarization layer 250 may planarize one or more steps caused due to the pixel driving circuit thereunder. The planarization layer 250 may include a multilayer structure of a first planarization layer 251 and a second planarization layer 252. For example, the planarization layer 250 may include a photo-reactive organic insulating material, such as a photosensitive polyimide resin, a photo-acryl resin, or a photosensitive photoresist. In an example, each of the first planarization layer 250 and the second planarization layer 251 may extend to the non-display area NAA surrounding the periphery of the display area AA.

A pixel contact electrode 255 may be disposed on the first planarization layer 251. The pixel contact electrode 255 may extend thorough the first planarization layer 251 and the passivation layer 247 so as to directly contact the second drain electrode 246 of the second transistor 240.

The light-emitting element 260 may be formed on the planarization layer 250. For example, the light-emitting element 260 may be disposed on the second planarization layer 252. The light-emitting element 260 may include a first electrode 261, a light-emitting layer 263, a second electrode 265, and a capping layer 267.

The light-emitting element 260 may be electrically connected to the pixel driving circuit via the first electrode 261. For example, the first electrode 261 may extend through the second planarization layer 252 so as to directly contact the pixel contact electrode 255. Accordingly, the first electrode 261 may be electrically connected to the second transistor 240 via the pixel contact electrode 255. The pixel contact electrode 255 may include a conductive material. For example, the pixel contact electrode 255 may include a metal material, such as aluminum (Al), chromium (Cr), copper (Cu), titanium (Ti), molybdenum (Mo), or tungsten (W). In an example, the pixel contact electrode 255 may have a multilayer structure of titanium layer/aluminum layer/titanium layer (Ti/Al/Ti).

The first electrode 261 may include a transparent conductive film. For example, the first electrode 261 may include ITO (Indium Tin Oxide) or IZO (Indium Zinc Oxide). Alternatively, the first electrode 261 may have a single-layer or a multi-layer structure including a reflective metal film made of one of silver (Ag), aluminum (Al), gold (Au), nickel (Ni), and chromium (Cr) or an alloy thereof. The first electrode 261 may also be referred to as a pixel electrode or an anode electrode.

A bank 262 may be disposed on the first electrode 261. The bank 262 may be disposed to cover an edge of the first electrode 261. A portion of the bank 262 may extend to the second planarization layer 252. A portion of an upper surface of the first electrode 261 not covered with the bank 262 so as to be exposed through the bank 262 may be the light emission area. The bank 262 may be made of an organic insulating material. The bank 262 may include, for example, photosensitive polyimide, photoacryl, or benzocyclobutene (BCB).

A spacer 264 may be further disposed on the bank 262. The spacer 264 may be disposed to prevent or suppress damage to the bank 262 and the first electrode 261 during the manufacturing or fabrication process. The spacer 264 may be made of the same material as that of the bank 262. The bank 262 and the spacer 264 may be stacked vertically to constitute an organic insulating structure 266.

The light-emitting layer 263 may be disposed on the first electrode 261. The light-emitting layer 263 may include a hole transport layer HTL, an organic light-emitting layer EML, an electron transport layer ETL, a hole blocking layer HBL, a hole injecting layer HIL, an electron blocking layer EBL, and an electron injecting layer EIL. The light-emitting layer 263 may have a multi-stack structure in which two or more organic emission layers EML are stacked.

The second electrode 265 may be disposed on the light-emitting layer 263. The second electrode 265 may be commonly connected to the light-emitting layer 263 formed in all pixels. Therefore, the second electrode 265 may also be referred to as a common electrode or a cathode electrode. The second electrode 265 may include a transflective conductive material. For example, the second or cathode electrode 265 may be made of a metal material, such as magnesium (Mg), silver (Ag), or an alloy (Ag—Mg) of silver (Ag) and magnesium (Mg). In an example, the second electrode 265 may include a transparent conductive layer, such as indium-tin-oxide (ITO) or indium-zinc-oxide (IZO).

The capping layer 267 may be disposed on the second electrode 265. The capping layer 267 may prevent light generated from the light-emitting layer 263 from being lost, thereby improving light extraction efficiency.

The encapsulation stack 270 may be disposed on the light-emitting element 260. The encapsulation stack 270 may protect the light-emitting element 260 from external oxygen or moisture. The encapsulation stack 270 may extend to the non-display area NAA outside the display area AA while covering the display area AA.

The encapsulation stack 270 may include a multilayer structure in which a first encapsulation layer 271, a second encapsulation layer 273, and a third encapsulation layer 275 are stacked. The second encapsulation layer 273 may be disposed between the first encapsulation layer 271 and the third encapsulation layer 275.

The first encapsulation layer 271 may be disposed on the capping layer 267. The second encapsulation layer 273 may be disposed on the first encapsulation layer 271. The second encapsulation layer 273 may cover the first encapsulation layer 271 and may have a sufficient thickness so as to have a flat upper surface. The second encapsulation layer 273 may prevent or block foreign substances from penetrating into the light-emitting element 260. The third encapsulation layer 275 may be disposed on the second encapsulation layer 273. Each of the first encapsulation layer 271 and the third encapsulation layer 275 may extend to the non-display area NAA surrounding the periphery of the display area AA.

Each of the first encapsulation layer 271 and the third encapsulation layer 275 may include an inorganic insulating material, and the second encapsulation layer 273 may include an organic insulating material. For example, each of the first encapsulation layer 271 and the third encapsulation layer 275 may include at least one of silicon nitride (SiNx), silicon oxide (SiOx), and silicon oxynitride (SiON). The second encapsulation layer 273 may include at least one of epoxy, polyimide, polyethylene, and acrylate.

The touch area 1300 may be disposed on the encapsulation stack 270. The touch area 1300 may include a touch buffer layer 277, a touch sensor 287, a touch interlayer insulating layer 282, a first touch protective layer 290, and a second touch protective layer 295.

The touch buffer layer 277 may be disposed on the third encapsulation layer 275. The touch buffer layer 277 may reduce stress between the encapsulation stack 270 and the layer of the touch sensor 287 to prevent or protect the encapsulation stack 270 and the light-emitting element 260 from being damaged. The touch buffer layer 277 may include an inorganic insulating material. For example, the touch buffer layer 277 may include silicon nitride (SiNx).

The touch sensor 287 may include a plurality of touch electrodes 285 and a bridge electrode 281. The plurality of touch electrodes 285 and the bridge electrode 281 may be disposed in different layers. For example, the bridge electrode 281 may be disposed on the touch buffer layer 277. The plurality of touch electrodes 285 may be disposed on the touch interlayer insulating layer 282. The plurality of touch electrodes 285 may include a first touch electrode 283 and a second touch electrode 284. The bridge electrode 281 may electrically connect adjacent first touch electrodes 283 to each other. To this end, the first touch electrodes 283 may extend through the touch interlayer insulating layer 282 so as to be connected to the bridge electrode 281. The touch interlayer insulating layer 282 may include an inorganic insulating material. For example, the touch interlayer insulating layer 282 may include silicon nitride (SiNx).

The first touch electrode 283, the second touch electrode 284, or the bridge electrode 281 may include a conductive material. The first touch electrode 283, the second touch electrode 284, or the bridge electrode 281 may include a single layer or a stack of multiple layers made of one of molybdenum (Mo), aluminum (Al), chromium (Cr), gold (Au), titanium (Ti), nickel (Ni), neodymium (Nd), and copper (Cu) or an alloy thereof.

Each of the touch buffer layer 277 and the touch interlayer insulating layer 282 may extend toward the non-display area NAA. The touch buffer layer 277 and the touch interlayer insulating layer 282 may be in contact with each other in the vertical direction in the non-display area NAA to form a touch insulating structure 280.

The first touch protective layer 290 may be disposed on the touch sensor 287. The first touch protective layer 290 may prevent or suppress damage to the touch sensor 287 from external impact and moisture. The first touch protective layer 290 may include an organic insulating material. For example, the first touch protective layer 290 may be made of a photosensitive acrylic-based or polyimide-based organic material.

The second touch protective layer 295 may be disposed on the first touch protective layer 290. The second touch protective layer 295 may further protect the touch sensor 287 from external impact and moisture. In addition, the second touch protective layer 295 may planarize one or more steps caused by patterns constituting the touch sensor 287 disposed thereunder. The second touch protective layer 295 may include an organic insulating material.

A polarizing layer 300 may be disposed on the second touch protective layer 295 of the touch area 1300. The polarizing layer 300 may be disposed on the touch area 1300 via a first adhesive member 305. The polarization layer 300 may suppress reflection of external light and may change a polarization state of light emitted from the light-emitting element 260 of the light-emitting area 1200. For example, the first adhesive member 305 may include a pressure-sensitive adhesives (PSA).

A cover substrate 400 may be disposed on the polarizing layer 300. The cover substrate 400 may protect the pixel driving circuit 1100, the light-emitting area 1200, and the touch area 1300. The cover substrate 400 may be referred to as a cover window, a window cover, or a cover glass.

The cover substrate 400 may include a glass substrate. An optical adhesive member 310 may be disposed between the polarizing layer 300 and the cover substrate 400. For example, the optical adhesive member 310 may include an optically clear adhesive (OCA) film.

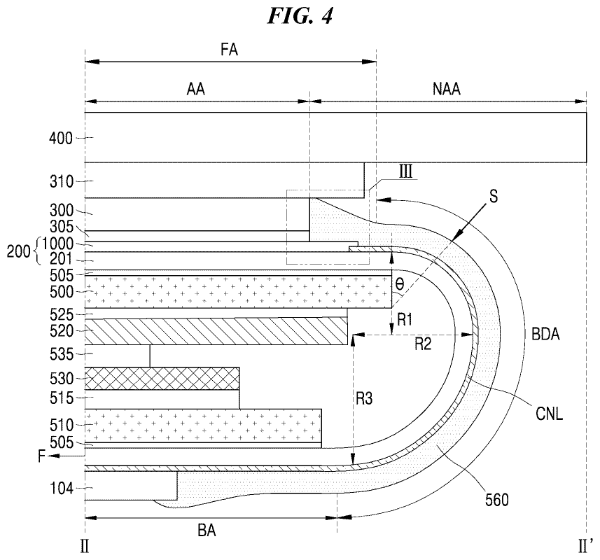

FIG. 4 is a diagram illustrating an example cross-sectional view taken along a line II-II′ in FIG. 2. FIG. 5 is a diagram illustrating an area III of FIG. 4.

As illustrated in FIGS. 4 and 5, the substrate 201 of the display panel 200 may include a front area FA on which an image is displayed, a rear area BA disposed to face a rear surface of the front area FA, and a bendable area BDA disposed between the front area FA and the rear area BA. The front area FA may include a display area AA and a non-display area NAA that is an area other than the display area AA. The display area AA and the non-display area NAA may be equally applied to a cover substrate 400. An area of the cover substrate 400 through which an image is displayed may be the display area AA.

The bendable area BDA may extend from one side of the front area FA of the display panel 200 (or of the substrate 201) and may be bendable. As the bendable area BDA of the display panel 200 (or of the substrate 201) has been bent, the printed circuit board 104 may be disposed in the rear area BA and facing away from the front area FA.

A first adhesive member 305, a polarizing layer 300, an optical adhesive member 310, and the cover substrate 400 may be disposed on the display panel 200.

Plates 500 and 510 may be disposed on a lower surface of the substrate 201 of the display panel 200. The plates 500 and 510 may support the substrate 201 made of a flexible material to maintain the shape thereof. The plates 500 and 510 may include, for example, polyethylene terephthalate (PET). The plates 500 and 510 may include a first plate 500 and a second plate 510 spaced apart from each other. The first plate 500 and the second plate 510 may be disposed in an area other than the bendable area BDA so that the bendable area BDA of the display panel 200 may be easily bent. For example, an area between the first plate 500 and the second plate 510 may be the bendable area BDA.

For example, an end of the first plate 500 may be a boundary of one side of the bendable area BDA, and an end of the second plate 510 facing the end of the first plate 500 may be a boundary of the other side of the bendable area BDA. The first plate 500 may support the display area AA and a portion of the non-display area NA adjacent to the display area AA, while the second plate 510 may support a portion of the substrate 201 of the display panel 200 on which the printed circuit board 104 is disposed. For example, since the first plate 500 is disposed in an area corresponding to and vertically overlapping the display area AA, the first plate 500 may have a larger size than that of the second plate 510 in the plan view of the display device.

A third plate 520 may be disposed under the first plate 500. In an example, the third plate 520 may include a heat dissipation layer. The heat dissipation layer is intended for imparting a heat dissipation effect to cope with a component generating heat and may include a material having high thermal conductivity. For example, the third plate 520 may include a metal material having high thermal conductivity.

A connection member 530 may be disposed on top of the second plate 510. The connection member 530 may fix a bent portion of the display panel 200 to maintain the bent shape thereof. The connection member 530 may include a pressure-sensitive adhesive including an optically transparent adhesive capable of fixing the third plate 520 and the second plate 510 in place.

A first adhesive layer 505 may be disposed between the first plate 500 and the substrate 201 of the display panel 200 and between the second plate 510 and the substrate 201 to fix each of the first plate 500 and the second plate 510 to the substrate 201. A second adhesive layer 525 may be disposed between the first plate 500 and the third plate 520 to fix first plate 500 and the third plate 520 to each other. A third adhesive layer 515 and a fourth adhesive layer 535 are disposed on a lower surface and an upper surface of the connection member 530, respectively, so as to fix the bent portion of the display panel 200 to maintain the bent shape thereof.

A signal line CNL may be disposed on the bendable area BDA of the substrate 201. The signal line CNL may be electrically connected to the driving array 1000 in the display area AA. The signal line CNL may extend on and along the bendable area BDA in the non-display area NAA and be electrically connected to the printed circuit board 104.

As shown in FIG. 5, an inorganic insulating structure MB may be disposed on a portion of the non-display area NAA between the display area AA and the bendable area BDA of the substrate 201. The inorganic insulating structure MB may be disposed not to extend to the bendable area BDA. The inorganic insulating structure MB may be embodied as an insulating layer of a multi-layer structure made of an inorganic insulating material and extending from the display area AA (see, e.g., FIG. 3). A link contact electrode LCT may be disposed on the inorganic insulating structure MB. The link contact electrode LCT may be made of the same material as that of and be formed in the same process as that of the second source electrode 245 or the second drain electrode 246 of the display area AA. The link contact electrode LCT may be electrically connected to data link lines connected to the plurality of pixels P of the display area AA via connecting electrodes respectively extending through the stack of multiple insulating layers constituting the inorganic insulating structure MB.

The first planarization layer 251 covering the link contact electrode LCT may be disposed on the inorganic insulating structure MB. The first planarization layer 251 may extend from the display area AA to the bendable area BDA. For example, the first planarization layer 251 may be disposed on the bendable area BDA so as to be in direct contact with the substrate 201. For example, the first planarization layer 251 may be disposed to extend from the front area FA and then across the bendable area BDA to the rear area BA. In this case, the first planarization layer 251 may have the same thickness over the entire bendable area BDA.

When a portion of the inorganic insulating structure MB corresponding to and vertically overlapping the bendable area BDA of the display panel is removed, a portion of the substrate 201 disposed under the inorganic insulating structure MB may also be removed to form an inclined surface. The inclined surface formed by removing the portion of the substrate 201 of the bendable area BDA may have a sharp inclination or a steep slope according to a process condition. When the inclined surface of the substrate 201 has the steep slope, defects in which a portion of the signal line CNL disposed on the sharply inclined surface may be broken or cut off may occur. For this reason, the first planarization layer 251 may be formed on the substrate 201, and the signal line CNL may be disposed on the first planarization layer 251. This may prevent or suppress the potential defect of the signal line CNL being broken due to the steep slope of the substrate 201 in the bendable area BDA.

The signal line CNL may be disposed on the first planarization layer 251. The signal line CNL may be disposed on the non-display area NAA and the bendable area BDA adjacent to the display area AA. The signal line CNL may extend through the first planarization layer 251 so as to be in contact with and be connected to the link contact electrode LCT. An area where the signal line CNL and the contact electrode LCT are in contact with each other and connected to each other may be referred to as a connection area CTA.

The signal line CNL may be made of the same material as that of and be formed in the same process as that of the pixel contact electrode 255 of the display area AA.

The second planarization layer 252 may be disposed on the signal line CNL. The second planarization layer 252 may extend to the bendable area BDA while covering the signal line CNL. For example, the second planarization layer 252 may be disposed to extend from and on and along the front area FA and then across and on and along the bendable area BDA onto and along the rear area BA. The organic insulating structure 266 may be disposed on the second planarization layer 252. The organic insulating structure 266 may be made of the same material as that of and be formed in the same process as that of each of the bank 262 and the spacer 264.

As illustrated in FIGS. 4 and 5, a protective layer 560 may be disposed on an outer surface of the bendable area BDA of the display panel 200. The protective layer 560 may cover a portion of the signal line CNL disposed on the bendable area BDA and may extend so as to be disposed on a partial area of the front area FA and a partial area of the rear area BA. On the front area FA, the protective layer 560 may cover a side surface of the polarizing layer 300. On the rear area BA, the protective layer 560 may cover a partial area of the printed circuit board 104. In an example, the protective layer 560 may be thicker than the polarizing layer 300.

The protective layer 560 may protect the signal line CNL from an external impact and prevent or block moisture from penetrating into the signal line CNL. In addition, the protective layer 560 may reinforce the rigidity of the substrate 201 of the display panel 200 in the bendable area BDA on which the first plate 500 and the second plate 510 are not disposed. For example, the protective layer 560 may include resin. However, embodiments of the present disclosure are not limited thereto.

A small curvature bending process (tight bending process) may be further performed on the substrate 201 of the display panel 200 to minimize a portion (or a bezel area) of the non-display area in an edge portion of the front area FA which may be visible to the viewer in front of the front area FA. In the small curvature bending process (tight bending process), after the bendable area BDA has been bent, a portion of the substrate 201 on which the second plate 510 is disposed may be pulled in a horizontal direction F as indicated in FIG. 4 such that the bendable area has an even smaller radius of curvature such that the portion (or a bezel area) of the non-display area in an edge portion of the front area FA which may be visible to the viewer in front of the front area FA may be minimized or further reduced.

Before the small curvature bending process (tight bending process) is performed, in the bending process of bending the bendable area BDA so that the rear area BA of the display panel 200 is located under the front area FA, the bendable area BDA may have the same radius of curvature over an entire bendable area BDA. However, as the small curvature bending process (tight bending process) is further performed to minimize or further reduce the bezel area visible to the viewer in front of the front area FA, the shape of the substrate 201 may be changed such that an asymmetric curvature may be formed.

For example, when a portion of the substrate 201 located in the rear area BA is pulled in the horizontal direction F, an end of the second plate 510 moves in the horizontal direction F, such that an end of the first plate 500 may protrude beyond the end of the second plate 510 (e.g., farther outward than the end of the second plate 510). Accordingly, a curvature of the portion of the signal line CNL disposed on the bendable area BDA may be nonuniform. For example, a curvature of the signal line CNL may be asymmetric such that curvature radii R1, R2, and R3 in different positions thereof corresponding to different positions of the bendable area BDA may be different from each other. The radius of curvature represents an amount by which the curve is bent. The radius of curvature at a point on a curve is the radius of the circle that best approximates the curve at that point. It can be considered a measure of how much a curve deviates from a straight line at a specific location. The smaller the radius of curvature, the more sharply or tightly the curve is bending. As the radius of curvature decreases, an amount by which the curve is bent may increase.

For example, a portion of the signal line CNL on a portion of the bendable area BDA disposed at a position close to the front area FA may have a first radius of curvature R1 from a locus around the end of the first plate 500. For example, a portion of the signal line CNL disposed on the most protruding portion (e.g., the most outward portion) of the bendable area BDA may have a second radius of curvature R2 from a locus around the end of the third plate 520. In addition, a portion of the signal line CNL disposed on a portion of the bendable area BDA at a position close to the rear area BA may have a third radius of curvature R3 from a locus around an end of the third plate 520. Among the first to third curvature radii R1, R2, and R3, the first curvature radius R1 may be the smallest, and the third curvature radius R3 may be the largest. Accordingly, a first curvature between a first curvature radius R1 and the second curvature radius R2 may be smaller than a second curvature between the second curvature radius R2 and the third curvature radius R3.

Where the curvatures of the different positions of the signal line CNL corresponding to the different positions of the bendable area BDA are different from each other, the stress may be concentrated on a specific portion of the bendable area BDA. The stress may be a force acting on a unit area. For example, a specific area of the bendable area BDA onto which the stress is concentrated may be a portion of the bendable area BDA at a position closer to the front area FA. The specific area onto which the stress is concentrated may be a crack occurrence critical point S at which the crack is more likely to occur in the signal line CNL than at other points. The crack occurrence critical point S may be a position having the first curvature radius R1 having the smallest radius of curvature and defining a first angle θ angular direction relative to the end (e.g., a side surface) of the first plate 500. The first angle θ may be about 45 degrees.

Accordingly, in another example embodiment of the present disclosure, a configuration capable of preventing or suppressing the crack occurrence critical point from occurring due to the concentration of stress onto the specific position of the bendable area BDA may be proposed.

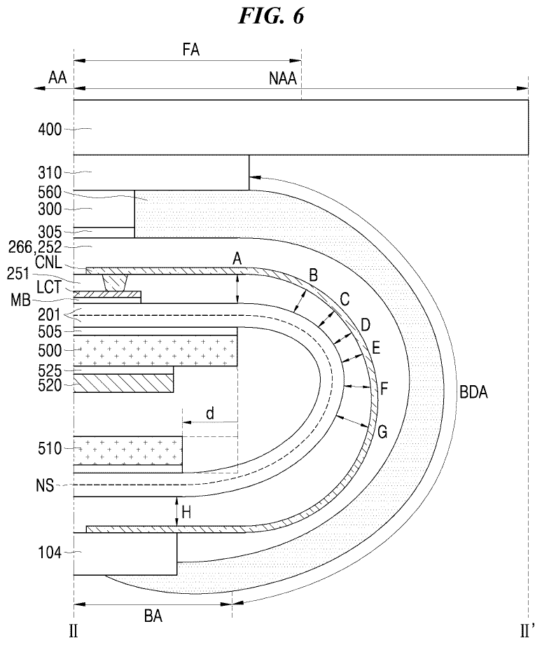

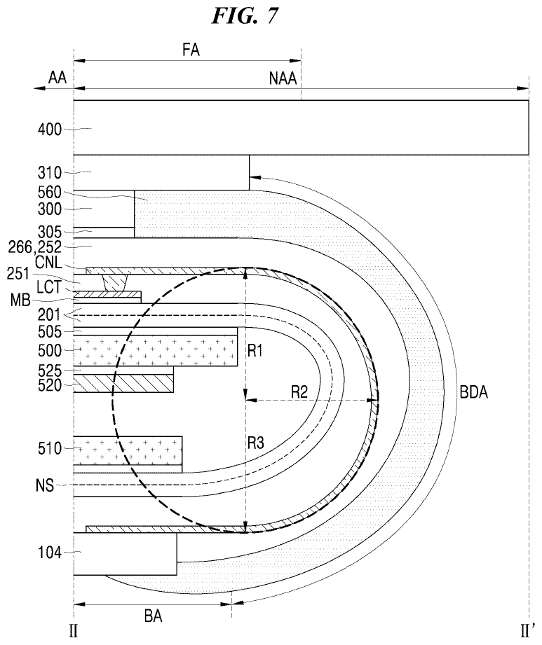

FIGS. 6 and 7 are diagrams illustrating a display device according to another example embodiment of the present disclosure. In FIGS. 6 and 7, the same components as those in the example embodiment of FIGS. 4 and 5 may employ the same reference numerals. Accordingly, redundant descriptions may be omitted or briefly set forth, and the differences therebetween will be mainly described.

In FIGS. 6 and 7, for convenience of illustration, only the substrate 201 among the components of the display panel 200, the inorganic insulating structure MB, the link contact electrode LCT, the signal line CNL, the first planarization layer 251, the second planarization layer 252, and the organic insulating structure 266 are illustrated. In this regard, each of the second planarization layer 252 and the organic insulating structure 266 is made of an organic insulating material and is illustrated as being embodied as a single layer. However, embodiments of the present disclosure are not limited thereto. For example, each of the second planarization layer 252 and the organic insulating structure 266 may be composed of multiple layers.

As illustrated in FIGS. 6 and 7, the substrate 201 of the display panel may include the front area FA in which an image is displayed, the rear area BA disposed to face a rear surface of the front area FA, and the bendable area BDA disposed between the front area FA and the rear area BA. The bendable area BDA may extend from one side of the front area FA of the display panel and be bent downwardly. As the bendable area BDA of the substrate 201 is bent, the printed circuit board 104 may be disposed on the rear area BA and facing away from the front area FA.

The inorganic insulating structure MB may be disposed on a portion of the non-display area NAA between the display area AA and the bendable area BDA of the substrate 201. The link contact electrode LCT may be disposed on the inorganic insulating structure MB.

The first planarization layer 251 covering the link contact electrode LCT may be disposed on the inorganic insulating structure MB. The first planarization layer 251 may extend from and on and along the front area FA and then across and on and along the bendable area BDA onto and along the rear area BA.

The first planarization layer 251 may have different thicknesses at different positions corresponding to different positions A, B, C, D, E, F, G, and H of the bendable area BDA. For example, at different positions corresponding to the first position A, the second position B, the third position C, the fourth position D, the fifth position E, the seventh position F, the eighth position G, and the ninth position H, the first planarization layer 251 may have different thicknesses. For example, the first position A may be a position at which the bendable area BDA starts, and the ninth position H may be a position at which the bendable area BDA ends. The second to eighth positions B to G may be positions in the bendable area BDA.

After the bending operation of bending the bendable area BDA has been performed, the small curvature bending process (tight bending process) may be further performed on the substrate 201 to further reduce the bezel area. The small curvature bending process (tight bending process) may be a process of pulling the end of the second plate 510 in the horizontal direction F (see FIG. 4) so that the end of the second plate 510 is located more inwardly than the end of the first plate 500 by a predetermined distance d. Accordingly, the substrate 201 may be bent such that a portion of the front area FA visible to the viewer in front thereof has a smaller radius of curvature and thus is reduced. Thus, an asymmetric curvature may be formed, and the greater stress may be concentrated on the portion having the smaller radius of curvature. Accordingly, the stress may be concentrated on the portion of the front area FA where the substrate 201 is bent to have the smaller radius of curvature. For example, the stress may be concentrated on a position corresponding to a position defining the 45 degrees angular direction relative to the end of the first plate 500. For example, the position defining the 45 degrees angular direction with respect to the end of the first plate 500 may be a position of the bendable area BDA corresponding to a position between the first position A closest to the front area FA and the seventh position F.

Accordingly, in a state in which the substrate 201 is bent to have the asymmetric curvature, the first planarization layer 251 may be patterned such that the thickness of the first planarization layer 251 changes as the first planarization layer 251 extends from the front area FA across the bendable area BDA to the rear area BA. With such varying thickness, the first planarization layer 251 may have an outer surface with a uniform radius of curvature as the first planarization layer 251 extends from the front area FA across the bendable area BDA to the rear area BA. Thus, the radius of curvature of the signal line CNL disposed on the first planarization layer 251 may be uniform along an entirety of the bendable area BDA. For example, the thickness of the first planarization layer 251 in an area between the first position A and the seventh position F where the substrate 201 is bent to have a smaller radius of curvature may be relatively smaller than those of the other positions F, G, and H. In addition, the signal line CNL may conformally extend on and along the first planarization layer 251 along the profile of the first planarization layer 251. Then, as shown in FIG. 7, the first radius of curvature R1, the second radius of curvature R2, and the third radius of curvature R3 may be equal to one another. Accordingly, a first curvature between the first curvature radius R1 and the second curvature radius R2 and a second curvature between the second curvature radius R2 and the third curvature radius R3 may be equal to each other.

However, the present disclosure is not limited to the example configurations in which the first radius of curvature R1, the second radius of curvature R2, and the third radius of curvature R3 are the same. For example, although the first to third curvature radii R1, R2, and R3 are not the same, the first planarization layer 251 may be patterned such that the thickness of the first planarization layer 251 changes in a conformal manner to the asymmetric curvature shape of the substrate 201. For example, the first planarization layer 251 may be patterned such that, where the substrate 201 has a smaller curvature, the thickness of the first planarization layer 251 may be smaller, thereby compensating for the curvature of the portion of the substrate 201 having the smaller curvature.

In addition, the substrate 201 may have a neutral plane NS defined therein. The neutral plane NS refers to a plane in which compressive stress and tensile stress counteract each other in a bending operation such that the net stress is a zero. As the position is closer to the neutral plane NS, the stress applied thereto may decrease.

As the first planarization layer 251 is constructed to have different thicknesses at different positions corresponding to different positions of the bendable area BDA, distances between the neutral plane NS of the substrate 201 having the asymmetric curvature and the outer surface of the first planarization layer 251 at different positions corresponding to the different positions of the bendable area BDA may be different from each other.

The signal line CNL may conformably extend along the profile of the outer surface of the first planarization layer 251 having the different thicknesses at different positions corresponding to different positions of the bendable area BDA. Accordingly, distances between the neutral plane NS of the substrate 201 having the asymmetric curvature and the signal line CNL at different positions corresponding to the different positions of the bendable area BDA may be different from each other.

For example, the position of the bendable area BDA between the first position A closest to the front area FA and the seventh position F may be an area onto which the stress is concentrated. Thus, the thickness of the first planarization layer 251 at a position corresponding to this position in the bendable area BDA may be smaller than the thickness at positions corresponding to positions in the bendable area BDA other than those from the first position A to the seventh position F. Accordingly, a portion of the signal line CNL disposed on the portion of the first planarization layer 251 corresponding to the area from the first position A to the seventh position F may be closer to the neutral plane NS.

Accordingly, the portion of the signal line CNL disposed on the portion of the first planarization layer 251 corresponding to the area from the first position A to the seventh position F may be closer to the neutral plane NS, such that such potential damages as cracks may be prevented or suppressed from occurring therein.

This may prevent or suppress the concentration of the stress on the specific point in the substrate 201 having the asymmetric curvature, thereby preventing or suppressing a potential defect such as a crack from occurring in the signal line CNL. Therefore, the signal provided to the display area AA may be more stably transmitted via the signal line CNL, such that the defect rate of the display device may be reduced. Then, the defect rate of the display device due to the damage of the signal line can be lowered, and thus the production energy required for the additional production of the display device may be reduced, thereby reducing the emission of greenhouse gas.

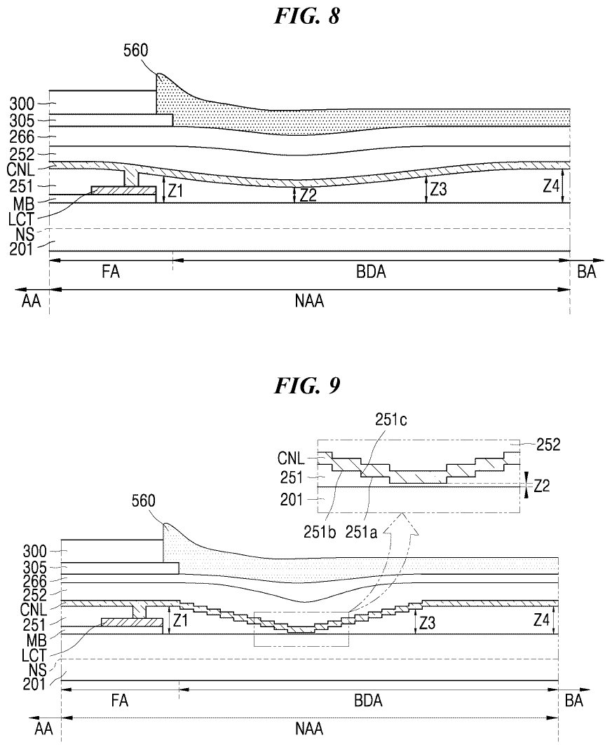

FIG. 8 is a view illustrating a bendable area according to another example embodiment of the present disclosure. FIG. 8 illustrates a state in which the display device is not bent. In FIG. 8, the same components as those in the example embodiment of FIGS. 4 and 5 may employ the same reference numerals. Accordingly, redundant descriptions may be omitted or briefly set forth, and differences therebetween will be mainly described.

As shown in FIG. 8, the inorganic insulating structure MB may be disposed on a portion of the non-display area NAA between the display area AA and the bendable area BDA of the substrate 201. The link contact electrode LCT may be disposed on the inorganic insulating structure MB. The link contact electrode LCT may be electrically connected to the lines that provide a signal or a voltage to the plurality of pixels P of the display area AA via the connecting electrodes respectively extending through the stack of multiple insulating layers constituting the inorganic insulating structure MB.

The first planarization layer 251 covering the link contact electrode LCT may be disposed on the inorganic insulating structure MB. The first planarization layer 251 may extend from and on and along the front area FA and then across and on and along the bendable area BDA onto and along the rear area BA. For example, the first planarization layer 251 may be disposed in the bendable area BDA so as to be in direct contact with the substrate 201.

The first planarization layer 251 may be constructed to have different thicknesses (or heights) at different positions thereof corresponding to different positions in the bendable area BDA. The first planarization layer 251 may be patterned by irradiating light of different exposure amounts to different positions thereof in a halftone mask process. The halftone mask may include, for example, a step tablet mask or a multitone mask. For example, a first area Z1, a second area Z2, a third area Z3, and a fourth area Z4 of the first planarization layer 251 may have different thicknesses. The first area Z1 of the first planarization layer 251 may be a position corresponding to and vertically overlapping the front area FA. The second area Z2 may be an area intended to have a relatively smallest radius of curvature in the bendable area BDA in the small curvature bending process (tight bending process) after the main bending operation. For example, the second area Z2 may be an area onto which the stress is concentrated and may be positioned at the position defining the first angle θ angular direction with respect to the end (or side surface) of the first plate 500. The third area Z3 may be closer to the rear area BA than the second area Z2 is. The fourth area Z4 may be adjacent to the rear area BA.

The thickness of the first planarization layer 251 may be the smallest in the second area Z2 as an area onto which the stress is concentrated, among the first to fourth areas Z1, Z2, Z3, and Z4. For example, the thickness of the first planarization layer 251 may gradually increase as the first planarization layer 251 extends from the second area Z2 toward the first area Z1 and/or from the second area Z2 toward the third area Z3. For example, the thickness of the first planarization layer 251 may be the largest in the fourth area Z4.

The signal line CNL may be disposed on an upper surface of the first planarization layer 251. The signal line CNL may be electrically connected to the link contact electrode LCT through a connecting electrode extending through a portion of the first planarization layer 251 on the front area FA. The signal line CNL may extend from and on and along the front area FA and then across and on and along the bendable area BDA onto and along the rear area BA.

The signal line CNL may conformally extend on and along a profile of the upper surface of the first planarization layer 251 having different thicknesses at different positions thereof corresponding to different positions in the bendable area BDA. Accordingly, the distances between the signal line CNL and the neutral plane NS at different positions of the signal line CNL corresponding to different positions in the bendable area BDA may be different from each other. A portion of the signal line CNL disposed in an area onto which the stress is concentrated may be located closer to the neutral plane NS. For example, the thickness of the first planarization layer 251 may be the smallest in the second area Z2 as an area onto which the stress is concentrated. In addition, the signal line CNL may be at the smallest distance from the neutral plane NS at the portion of the signal line CNL disposed on the second area Z2 of the first planarization layer 251. In other words, the portion of the signal line CNL disposed on the second area Z2 of the first planarization layer 251 may be located closer to the neutral plane NS than the other portions of the signal line CNL respectively disposed on the other areas Z1, Z3, and Z4 of the first planarization layer 251.

The neutral plane NS refers to the plane in which compressive stress and tensile stress counteract each other in the bending operation, and the stress is not generated or the net stress is zero. As the portion of the signal line CNL is disposed closer to the neutral plane NS, the mechanical stress applied thereto decreases, so that a potential damage to the signal line CNL, such as a crack in the signal line, may be suppressed.

Accordingly, the signal line CNL disposed on the first planarization layer 251 in the bendable area BDA may be located closest to the neutral plane NS at the second area Z2 of the first planarization layer 251. Thus, even when the small curvature bending process (tight bending process) is further performed after the main bending operation is performed, such potential damages as cracks may be prevented or suppressed from occurring in this portion of the signal line CNL.

In addition, the first planarization layer 251 may be patterned such that the curvature o its outer surface (that is, the upper surface on which the signal line CNL is disposed before the bending process) in the bent state may vary along the bendable area BDA in the conformal manner to the curvature of the substrate 201 varying along the bendable area BDA. For example, the substrate 201 may have the asymmetric curvature in the bendable area BDA. In this regard, the signal line CNL may have the same radius of curvature in the entire area of the bendable area BDA. Accordingly, the area of the signal line CNL onto which the stress may be concentrated due to the asymmetric curvature of the substrate 201 may be prevented or suppressed from occurring, such that potential damages like cracks may be prevented or suppressed from occurring in the signal line CNL.

The second planarization layer 252 and the organic insulating structure 266 may be vertically stacked on the signal line CNL.

The first adhesive member 305 and the polarizing layer 300 may be vertically stacked over the substrate 201 in the front area FA of the display panel. The protective layer 560 may be disposed on the outer surface of the display panel 200 in the bendable area BDA in the bent state. In a flat state as shown in FIG. 8, the protective layer 560 may be disposed on a portion of the organic insulating structure 266 on the bendable area BDA of the substrate 201. The protective layer 560 may extend from and along and on a partial area of the front area FA and to and along and on a partial area of the rear area BA. In the front area FA, the protective layer 560 may cover the side surface of the polarizing layer 300. In an example, the protective layer 560 may be thicker than the polarizing layer 300.

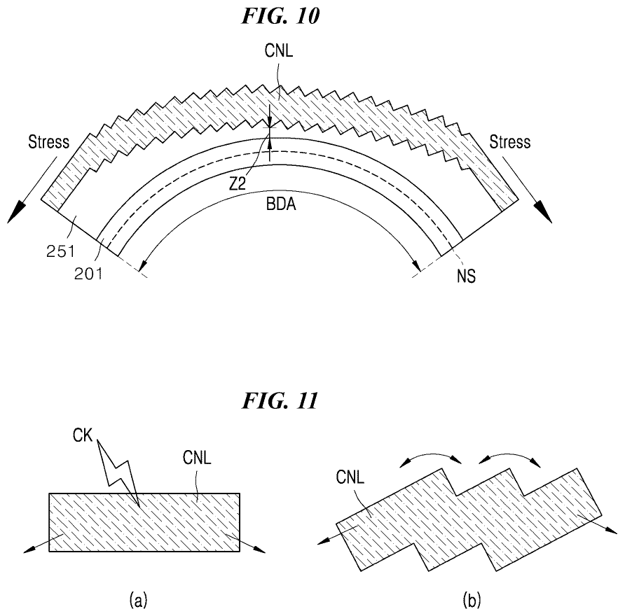

FIG. 9 is a view illustrating a bendable area according to still another example embodiment of the present disclosure. FIG. 9 illustrates a state in which the display device is not bent, that is, in the flat state. FIGS. 10 and 11 are diagrams illustrating stress during a bending operation. In FIG. 9, the same components as those of the example embodiment of FIG. 8 may employ the same reference numerals. Accordingly, redundant descriptions may be omitted or briefly set forth, and differences therebetween will be mainly described.

As shown in FIG. 9, the inorganic insulating structure MB and the link contact electrode LCT may be disposed on the substrate 201. The first planarization layer 251 covering the link contact electrode LCT may be disposed on the inorganic insulating structure MB.

The first planarization layer 251 may be constructed in a stepwise structure having step resulting from the different thicknesses thereof at different positions along the bendable area BDA. For example, the first planarization layer 251 may include the first area Z1, the second area Z2, the third area Z3, and the fourth area Z4. The first area Z1 of the first planarization layer 251 may be a position corresponding to and vertically overlapping the front area FA. The second area Z2 may be an area in which the substrate 201 is to have the smallest radius of curvature in the bendable area BDA in the small curvature bending process (tight bending process) after the main bending operation. For example, the second area Z2 may be an area onto which the stress is concentrated and may be positioned at a position defining the first angle θ angular direction with respect to the end of the first plate 500 (see FIG. 4). The third area Z3 may be closer to the rear area BA than the second area Z2 is. The fourth area Z4 may be adjacent to the rear area BA.

The thickness of the first planarization layer 251 may be the smallest in the second area Z2 as the area onto which the stress may be concentrated, among the first to fourth areas Z1, Z2, Z3, and Z4. A first stepwise structure having a plurality of steps resulting from different thicknesses may be formed in an area from the second area Z2 toward the first area Z1. A second stepwise structure having a plurality of steps resulting from different thicknesses may be formed in an area from the second area Z2 toward the third area Z3. In the first stepwise structure and the second stepwise structure, a step caused by the smallest thickness in the first stepwise structure and a step caused by the smallest thickness in the second stepwise structure may be connected to each other in an integral manner with each other. A thickness of the first planarization layer 251 may be the largest in each of the first area Z1 and the fourth area Z4.

The first stepwise structure of the first planarization layer 251 including the stepwise structure may include a first surface 251a extending in a first direction parallel to the upper surface of the substrate 201 (e.g., in the flat state), a second surface 251b extending in the first direction parallel to the upper surface of the substrate 201 and disposed at a higher or lower position than the first surface 251a, and a side surface 251c extending in a direction perpendicular to the upper surface of the substrate 201 and connecting the first surface 251a and the second surface 251b to each other. For example, the steps of the first stepwise structure may be composed of the first surface 251a, the second surface 251b, and the side surface 251c connecting the first surface 251a and the second surface 251b which are arranged in the first direction and connected to each other. For example, the first direction may be a direction from the second area Z2 toward the first area Z1.

The second stepwise structure of the first planarization layer 251 including the stepwise structure may include a first surface 251a extending in a second direction parallel to the upper surface of the substrate 201 (e.g., in the flat state), a second surface 251b extending in the second direction parallel to the upper surface of the substrate 201 and disposed at a higher or lower position than the first surface 251a, and a side surface 251c extending in a direction perpendicular to the upper surface of the substrate 201 and connecting the first surface 251a and the second surface 251b to each other. For example, the steps of the second stepwise structure may be composed of the first surface 251a, the second surface 251b, and the side surface 251c connecting the first surface 251a and the second surface 251b which are arranged in the second direction and connected to each other. For example, the second direction may be a direction from the second area Z2 toward the third area Z3.

The stepwise structure of the first planarization layer 251 may be formed by irradiating light of different exposure amounts to different positions thereof in a halftone mask process.

The signal line CNL may be disposed on the first planarization layer 251. The signal line CNL may conformally extend on and along a profile of the stepped upper surface of the first planarization layer 251 including the stepwise structure. For example, the signal line CNL may be disposed on the first surface 251a, the second surface 251b, and the side surface 251c of the first planarization layer 251. Accordingly, the signal line CNL may be constructed to have a stepwise structure conformal to the stepwise structure of the first planarization layer 251.

The distances from the different positions of the signal line CNL having the stepwise structure to the neutral plane NS in the bendable area BDA may be different from each other in the stepwise manner. For example, the thickness of the first planarization layer 251 may be the smallest in the second area Z2 as the area onto which the stress may be concentrated. Accordingly, the signal line CNL may be at the smallest distance from the neutral plane NS at the portion of the signal line CNL disposed on the second area Z2 of the first planarization layer 251. In other words, the portion of the signal line CNL disposed on the second area Z2 of the first planarization layer 251 may be located closer to the neutral plane NS than the other portions of the signal line CNL respectively disposed on the other areas Z1, Z3, and Z4 of the first planarization layer 251.

As illustrated in FIG. 10, as the bendable area BDA of the substrate 201 is bent in the bending operation, the distance between the portion of the signal line CNL disposed on the second area Z2 of the first planarization layer 251and the neutral plane NS becomes smaller, so that the tensile stress applied to the portion of the signal line CNL may be reduced. Accordingly, potential damages like cracks may be prevented or suppressed from occurring in the portion of the signal line CNL disposed on the second area Z2 of the first planarization layer 251.

In addition, durability against the tensile stress may be enhanced due to the shape of the signal line CNL constructed in the stepwise structure. For example, since the stress may be dispersed across a stepped portion extending between the first surface 251a and the side surface 251c and between the side surface 251c and the second surface 251b of the stepwise structure, durability against the tensile stress applied thereto during the bending operation may be enhanced.

For example, as illustrated in FIG. 11, in the example case (a) of the signal line CNL constructed in a flat structure, a direction in which the stress is dispersed is limited to the horizontal direction of the signal line CNL as indicated by the arrow. Thus, the stress may be concentrated in the vertical direction, such that a crack CK may occur in the signal line CNL. However, in the example case (b) of the signal line CNL constructed in the stepwise structure, the stress may be dispersed not only in the horizontal direction but also in the stepwise structure, thereby preventing or suppressing the stress from being concentrated. This may prevent or suppress potential cracks from occurring due to stress concentration.

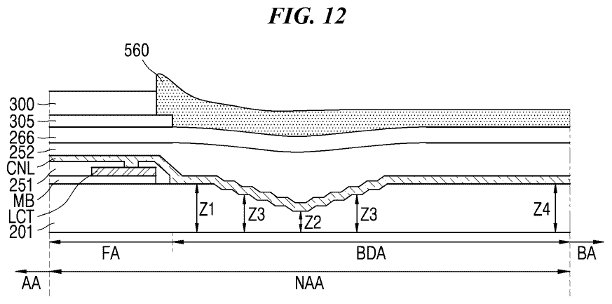

FIG. 12 is a view illustrating a bendable area according to still yet another example embodiment of the present disclosure. FIG. 12 illustrates a state in which the display device is not bent, that is, in the flat state. In FIG. 12, the same components as those of the example embodiment of FIG. 9 may employ the same reference numerals. Accordingly, redundant descriptions may be omitted or briefly set forth, and differences therebetween will be mainly described.

As illustrated in FIG. 12, the inorganic insulating structure MB and the link contact electrode LCT may be disposed on the substrate 201. The first planarization layer 251 covering the link contact electrode LCT may be disposed on the inorganic insulating structure MB. The first planarization layer 251 may be disposed on the front area FA of the display panel. For example, the first planarization layer 251 may be disposed not to be on the bendable area BDA of the substrate 201.

The substrate 201 may be constructed to have different thicknesses at different positions thereof corresponding to different positions in the bendable area BDA. For example, the thickness of the substrate 201 in the bendable area BDA may refer to a thickness in the vertical direction from a bottom, rear, or back surface to an upper or front surface of the substrate 201 (e.g., in the flat state). The substrate 201 may include an organic insulating material including polyimide (PI). Accordingly, a halftone mask may be disposed on the substrate 201, and light may be irradiated to the substrate such that light of different exposure amounts are irradiated to the different positions of the substrate 201 in the bendable area BDA. The halftone mask may include, for example, a step tablet mask or a multitone mask.

The bendable area BDA of the substrate 201 may be constructed in a stepwise structure in which steps caused by the different thicknesses gradually change and are consecutively arranged as the substrate extends along the bendable area BDA. For example, the bendable area BDA of the substrate 201 may include a first area Z1, a second area Z2, third areas Z3, and a fourth area Z4. The first area Z1 may be adjacent to the front area FA. The second area Z2 may be an area having a smallest radius of curvature in the bendable area BDA in a small curvature bending process (tight bending process) after the main bending operation. For example, the second area Z2 may be an area onto which the stress is concentrated and may be positioned at a position defining the first angle θ angular direction with respect to the end of the first plate 500 (see FIG. 4). The third areas Z3 may respectively be at both sides of the second area Z2 and may respectively be closer to the front area FA and the rear area BA than the second area Z2 is. The fourth area Z4 may be adjacent to the rear area BA.

The thickness of the substrate 201 may be the smallest in the second area Z2 as an area onto which the stress may be concentrated, among the first to fourth areas Z1, Z2, Z3, and Z4. For example, the thickness of the substrate 201 may gradually increase as the substrate 210 extends from the second area Z2 across the third area Z3 toward the first area Z1 or from the second area Z2 across the third area Z3 toward the fourth area Z4. For example, the thickness of the substrate 201 may be the largest in the first area Z1 or the fourth area Z4.

The signal line CNL may be disposed on the first planarization layer 251 on the front area FA. The signal line CNL may be electrically connected to the link contact electrode LCT via the connecting electrode extending through the portion of the first planarization layer 251 on the front area FA. The signal line CNL may extend from and on and along the front area FA and then across and on and along the bendable area BDA onto and along the rear area BA. The signal line CNL may be directly disposed on the substrate 201 in the bendable area BDA. The signal line CNL may be in direct contact with the substrate 201 in the bendable area BDA. Accordingly, the signal line CNL may be constructed in a stepwise structure conformal to the stepwise structure of the upper surface of the substrate 201 in the bendable area BDA.

The distances between the different positions of the signal line CNL constructed in the stepwise structure and the neutral plane in the bendable area BDA of the substrate 201 may be different from each other. For example, the thickness of the substrate 201 may be the smallest in the second area Z2 as an area onto which the stress may be concentrated. Accordingly, the signal line CNL may be at the closest distance from the neutral plane at the portion of the signal line CNL disposed on the second area Z2 of the substrate 201, thereby preventing or suppressing the stress from being concentrated thereon during the bending operation, thereby preventing or suppressing potential cracks from occurring in the signal line CNL. This may prevent or protect the signal line CNL from being damaged.

A display panel and a display device including the same according to various aspects and embodiments of the present disclosure may be described as follows.

In one or more aspects of the present disclosure, a display panel has a front area including a display area and a non-display area outside the display area, a rear area under the front area, and a bendable area connected between the front area and the rear area, the display panel being bent in the bending area and including: an organic insulating film disposed in the front area, the rear area, and the bendable area and having a curvature in the bendable area; and a signal line on the organic insulating film in the bendable area, wherein the organic insulating film includes a plurality of regions having different thicknesses in the bendable area.

In accordance with some embodiments, the display panel may further include: a substrate in the front area, the rear area, and the bendable area; and a first planarization layer over the substrate at least in the display area, wherein the organic insulating film may be one of the substrate and the first planarization layer.

In accordance with some embodiments, the display panel may further include a second planarization layer on the organic insulating film and covering the signal line.

In accordance with some embodiments, the substrate may have an asymmetric curvature in the bendable area, a first portion of the substrate in the bendable area adjacent to the front area may have a first radius of curvature, a second portion of the substrate in the bendable area may have a second radius of curvature, the second portion being disposed between the first portion of the substrate and the rear area, a third portion of the substrate in the bendable area may have a third radius of curvature, the third portion being disposed between the second portion of the substrate and the rear area, and the first radius of curvature may be smaller than each of the second radius of curvature and the third radius of curvature.

In accordance with some embodiments, the organic insulating film may be the first planarization layer, the first planarization layer may include a first region corresponding to the first portion of the substrate, a second region corresponding to the second portion of the substrate, and a third region corresponding to the third portion of the substrate, among the plurality of regions. The first region of the first planarization layer may have a first thickness, the second region of the first planarization layer may have a second thickness, and the third region of the first planarization layer may have a third thickness. The second thickness may be smaller than at least one of the second thickness and the third thickness. The signal line may be disposed on an outer surface of the first planarization layer in the bendable area.

In accordance with some embodiments, the substrate may have a neutral plane defined therein, and a distance between a portion of the signal line disposed on the first region of the first planarization layer and the neutral plane of the substrate may be greater than a distance between a portion of the signal line disposed on the second region of the first planarization layer and the neutral plane of the substrate.

In accordance with some embodiments, the outer surface of the first planarization layer may have a same radius of curvature at the first region, the second region, and the third region, and the signal line may have a uniform radius of curvature over the first region, the second region, and the third region of the first planarization layer.

In accordance with some embodiments, the organic insulating film may be the first planarization layer, and the plurality of regions of the organic insulating film may include first, second, and third regions of the first planarization layer disposed in order between the front area and the rear area, the second region being between the first region and the third region. The substrate may have an asymmetric curvature in the bendable area, and an outer surface of the first planarization layer may have a stepwise structure including a plurality of steps arranged along the bendable area at different distances from the substrate.

In accordance with some embodiments, the stepwise structure of the first planarization layer may include: a first stepwise structure including connected steps having increasing heights arranged from the second region toward the first region adjacent to the front area, among the plurality of steps; and a second stepwise structure including other steps having increasing heights arranged from the second region toward the third region, among the plurality of steps. A step at the second region may have the smallest height among the plurality of steps.

In accordance with some embodiments, one of the plurality of steps may include: a first surface extending in a first direction toward the front area; a second surface extending in a second direction toward the rear area and disposed at a different vertical level from the first surface; and a side surface connecting the first surface and the second surface.

In accordance with some embodiments, the signal line may be disposed on and along the first surface, the second surface, and the side surface.

In accordance with some embodiments, the organic insulating film may be the substrate, and the plurality of regions of the organic insulation film may include a first portion, a second portion, and a third portion of the substrate arranged in order between the front area and the rear area.

In accordance with some embodiments, the display panel may further include a second planarization layer on the signal line in the bendable area. The first planarization layer may be further disposed over the substrate in the non-display area of the front area and not extend to the bendable area. The signal line may be directly on the substrate in the bendable area.

In accordance with some embodiments, the substrate may have an asymmetric curvature in the bendable area, the first portion of the substrate in the bendable area may be adjacent to the front area have a first radius of curvature, the second portion of the substrate in the bendable area may have a second radius of curvature, the second portion being disposed between the first portion of the substrate and the rear area, the third portion of the substrate in the bendable area may have a third radius of curvature, the third portion being disposed between the second portion of the substrate and the rear area. The first radius of curvature may be smaller than each of the second radius of curvature and the third radius of curvature. The first portion of the substrate may have a first thickness, the second portion of the substrate may have a second thickness, and the third portion of the substrate may have a third thickness. The second thickness may be smaller than at least one of the first thickness and the third thickness.

In accordance with some embodiments, the substrate may ahve a neutral plane defined therein, and a distance between a portion of the signal line disposed on the first portion of the substrate and the neutral plane of the substrate may be greater than a distance between a portion of the signal line disposed on the second portion of the substrate and the neutral plane of the substrate.

In accordance with some embodiments, the signal line may extend from the front area across the bendable area to the rear area.

In accordance with some embodiments, the display panel may further include: a substrate in the front area, the rear area, and the bendable area; a first planarization layer on the substrate at least in the display area; a pixel driving circuit including at least one transistor on the substrate and under the first planarization layer in the display area; a light-emitting element on the pixel driving circuit; a pixel contact electrode electrically connecting the pixel driving circuit and the light-emitting element; and a touch sensor on the light-emitting element. The at least one transistor may include a semiconductor layer, a gate electrode overlapping the semiconductor layer, a gate insulating layer between the semiconductor layer and the gate electrode, and a source electrode and a drain electrode electrically connected respectively to opposing sides of the semiconductor layer.

In accordance with some embodiments, the display panel may further include a link contact electrode under the signal line in the front area and electrically connected to the signal line, wherein the link contact electrode may include a same material included in at least one of the source electrode and the drain electrode.

In accordance with some embodiments, the signal line may include a same material included in the pixel contact electrode.

In one or more other aspects of the present disclosure, a display device includes: the display panel according any of the above example embodiments of the present disclosure; a printed circuit board on the rear area of the display panel; a polarizing layer on the front area of the display panel; a cover member on the polarizing layer; and a protective layer on an outer surface of the display panel in the bendable area and extending to the front area and the rear area of the display panel.

Although some example embodiments of the present disclosure have been described above with reference to the accompanying drawings, the present disclosure may not be limited to those example embodiments and may be implemented in various different forms. Those of ordinary skill in the technical field to which the present disclosure belongs will be able to appreciate that the present disclosure may be implemented in other specific forms without changing or departing from the technical idea or features of the present disclosure. Therefore, it should be understood that the example embodiments as described above are not restrictive but illustrative in all respects.

What is claimed is:

1. A display panel having a front area including a display area and a non-display area outside the display area, a rear area under the front area, and a bendable area connected between the front area and the rear area, the display panel being bent in the bendable area and comprising:
an organic insulating film disposed in the front area, the rear area, and the bendable area and having a curvature in the bendable area; and
a signal line on the organic insulating film in the bendable area,
wherein the organic insulating film includes a plurality of regions having different thicknesses in the bendable area.

2. The display panel of claim 1, further comprising:
a substrate in the front area, the rear area, and the bendable area; and
a first planarization layer over the substrate at least in the display area,
wherein the organic insulating film is one of the substrate and the first planarization layer.

3. The display panel of claim 2, further comprises:
a second planarization layer on the organic insulating film and covering the signal line.

4. The display panel of claim 2, wherein:
the substrate has an asymmetric curvature in the bendable area;
a first portion of the substrate in the bendable area adjacent to the front area has a first radius of curvature;
a second portion of the substrate in the bendable area has a second radius of curvature, the second portion being disposed between the first portion of the substrate and the rear area;
a third portion of the substrate in the bendable area has a third radius of curvature, the third portion being disposed between the second portion of the substrate and the rear area; and
the first radius of curvature is smaller than each of the second radius of curvature and the third radius of curvature.

5. The display panel of claim 4, wherein:
the organic insulating film is the first planarization layer;
the first planarization layer includes a first region corresponding to the first portion of the substrate, a second region corresponding to the second portion of the substrate, and a third region corresponding to the third portion of the substrate, among the plurality of regions;
the first region of the first planarization layer has a first thickness, the second region of the first planarization layer has a second thickness, and the third region of the first planarization layer has a third thickness;
the second thickness is smaller than at least one of the second thickness and the third thickness; and
the signal line is disposed on an outer surface of the first planarization layer in the bendable area.

6. The display panel of claim 5, wherein:
the substrate has a neutral plane defined therein; and
a distance between a portion of the signal line disposed on the first region of the first planarization layer and the neutral plane of the substrate is greater than a distance between a portion of the signal line disposed on the second region of the first planarization layer and the neutral plane of the substrate.

7. The display panel of claim 5, wherein:
the outer surface of the first planarization layer has a same radius of curvature at the first region, the second region, and the third region; and
the signal line has a uniform radius of curvature over the first region, the second region, and the third region of the first planarization layer.

8. The display panel of claim 2, wherein:
the organic insulating film is the first planarization layer;
the plurality of regions of the organic insulating film include first, second, and third regions of the first planarization layer disposed in order between the front area and the rear area, the second region being between the first region and the third region;
the substrate has an asymmetric curvature in the bendable area; and
an outer surface of the first planarization layer has a stepwise structure including a plurality of steps arranged along the bendable area at different distances from the substrate.

9. The display panel of claim 8, wherein the stepwise structure of the first planarization layer includes:
a first stepwise structure including connected steps having increasing heights arranged from the second region toward the first region adjacent to the front area, among the plurality of steps; and
a second stepwise structure including other steps having increasing heights arranged from the second region toward the third region, among the plurality of steps, and
wherein a step at the second region has the smallest height among the plurality of steps.

10. The display panel of claim 8, wherein one of the plurality of steps includes:
a first surface extending in a first direction toward the front area;
a second surface extending in a second direction toward the rear area and disposed at a different vertical level from the first surface; and
a side surface connecting the first surface and the second surface.

11. The display panel of claim 10, wherein the signal line is disposed on and along the first surface, the second surface, and the side surface.

12. The display panel of claim 2, wherein:
the organic insulating film is the substrate; and
the plurality of regions of the organic insulation film include a first portion, a second portion, and a third portion of the substrate arranged in order between the front area and the rear area.

13. The display panel of claim 12, further comprising:
a second planarization layer on the signal line in the bendable area,
wherein the first planarization layer is further disposed over the substrate in the non-display area of the front area and does not extend to the bendable area, and
wherein the signal line is directly on the substrate in the bendable area.

14. The display panel of claim 12, wherein:
the substrate has an asymmetric curvature in the bendable area;
the first portion of the substrate in the bendable area is adjacent to the front area and has a first radius of curvature;
the second portion of the substrate in the bendable area has a second radius of curvature, the second portion being disposed between the first portion of the substrate and the rear area;
the third portion of the substrate in the bendable area has a third radius of curvature, the third portion being disposed between the second portion of the substrate and the rear area;
the first radius of curvature is smaller than each of the second radius of curvature and the third radius of curvature;
the first portion of the substrate has a first thickness, the second portion of the substrate has a second thickness, and the third portion of the substrate has a third thickness; and
the second thickness is smaller than at least one of the first thickness and the third thickness.

15. The display panel of claim 14, wherein:
the substrate has a neutral plane defined therein; and
a distance between a portion of the signal line disposed on the first portion of the substrate and the neutral plane of the substrate is greater than a distance between a portion of the signal line disposed on the second portion of the substrate and the neutral plane of the substrate.

16. The display panel of claim 1, wherein the signal line extends from the front area across the bendable area to the rear area.

17. The display panel of claim 1, further comprising:
a substrate in the front area, the rear area, and the bendable area;
a first planarization layer on the substrate at least in the display area;
a pixel driving circuit including at least one transistor on the substrate and under the first planarization layer in the display area;
a light-emitting element on the pixel driving circuit;
a pixel contact electrode electrically connecting the pixel driving circuit and the light-emitting element; and
a touch sensor on the light-emitting element,
wherein the at least one transistor includes a semiconductor layer, a gate electrode overlapping the semiconductor layer, a gate insulating layer between the semiconductor layer and the gate electrode, and a source electrode and a drain electrode electrically connected respectively to opposing sides of the semiconductor layer.

18. The display panel of claim 17, further comprising:
a link contact electrode under the signal line in the front area and electrically connected to the signal line,
wherein the link contact electrode includes a same material included in at least one of the source electrode and the drain electrode.

19. The display panel of claim 17, wherein the signal line includes a same material included in the pixel contact electrode.

20. A display device, comprising:
the display panel according to claim 1;
a printed circuit board on the rear area of the display panel;
a polarizing layer on the front area of the display panel;
a cover member on the polarizing layer; and
a protective layer on an outer surface of the display panel in the bendable area and extending to the front area and the rear area of the display panel.
